(19) United States
(12) Patent Application Publication
(10) Pub. No.: US 2026/0032915 A1
(43) Pub. Date: Jan. 29, 2026

(54) TRANSISTOR CONTACT STRUCTURE AND METHOD

(71) Applicant: Micron Technology, Inc., Boise, ID (US)

(72) Inventors: Byung Yoon Kim, Boise, ID (US); Kyuseok Lee, Meridian, ID (US); Jun Ho Lee, Meridian, ID (US); Deokhan Bae, Meridian, ID (US); Mark Zaleski, Boise, ID (US); Robert B. Kerr, Boise, ID (US)

(21) Appl. No.: 19/276,751

(22) Filed: Jul. 22, 2025

Related U.S. Application Data
(60) Provisional application No. 63/674,509, filed on Jul. 23, 2024.

(51) Int. Cl. H10B 43/40; G11C 16/08; G11C 16/26; H10B 41/40

(52) U.S. Cl. CPC H10B 43/40; G11C 16/08; G11C 16/26; H10B 41/40

(57) ABSTRACT

Apparatus and methods are disclosed, including transistors, semiconductor devices and systems. Example semiconductor devices and methods include an isolation structure within a substrate, and two layers of different dielectric material including a first dielectric layer and a second silicon oxide layer, both layers located over the isolation structure. Examples are further shown that include a first contact and a second contact both passing through a first dielectric of the two layers with side surfaces of the first contact and the second contact surrounded by the first dielectric.

### PRIORITY APPLICATION

This application claims the benefit of priority to U.S. Provisional Application Ser. No. 63/674,509, filed Jul. 23, 2024, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to transistor structures in complementary metal oxide semiconductor (CMOS) devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2A illustrates selected transistors in a stage of manufacture in accordance with some example embodiments.

FIG. 2B illustrates the selected transistors from FIG. 2A in another stage of manufacture in accordance with some example embodiments.

FIG. 2C illustrates the selected transistors from FIG. 2A in another stage of manufacture in accordance with some example embodiments.

FIG. 3A illustrates selected transistors in a stage of manufacture in accordance with some example embodiments.

FIG. 3B illustrates the selected transistors from FIG. 3A in another stage of manufacture in accordance with some example embodiments.

FIG. 3C illustrates the selected transistors from FIG. 3A in another stage of manufacture in accordance with some example embodiments.

FIG. 3D illustrates the selected transistors from FIG. 3A in another stage of manufacture in accordance with some example embodiments.

FIG. 3E illustrates the selected transistors from FIG. 3A in another stage of manufacture in accordance with some example embodiments.

FIG. 4 illustrates an example method flow diagram in accordance with other example embodiments.

FIG. 5 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

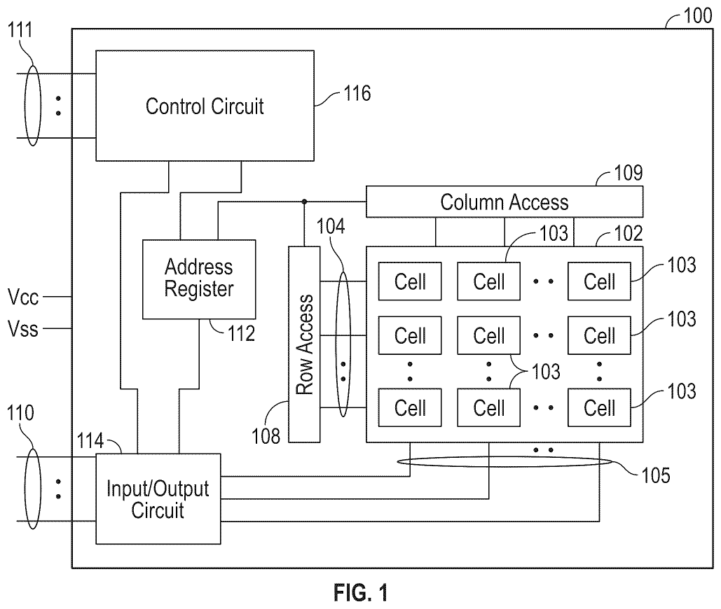

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

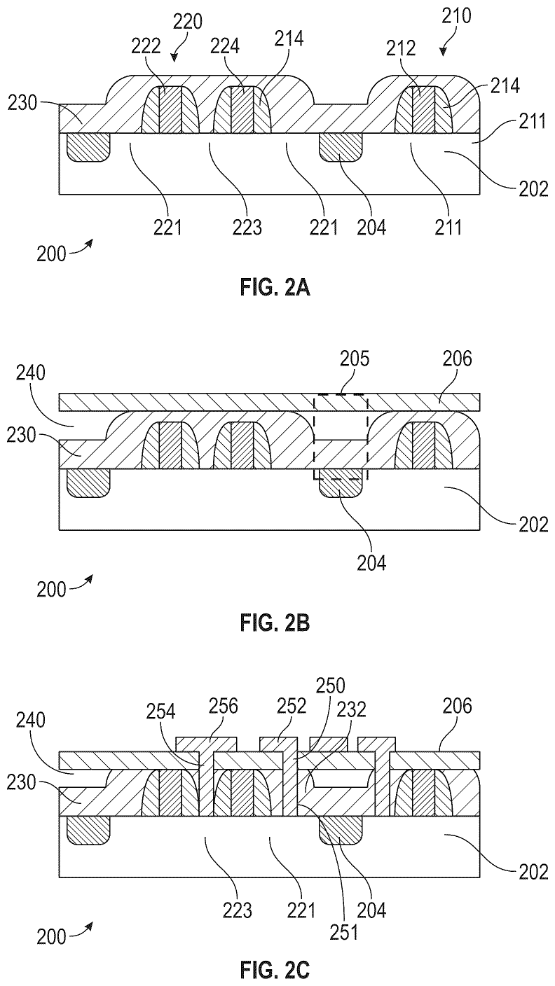

Memory cells 103 and other circuits 114, 116, etc. may include transistors and utilize methods as described in more detail in FIGS. 2A-4. In one example, memory arrays 102 include RAM storage, and peripheral circuits such as circuits 114, 116, 108, 109, etc. may include transistors as described in more detail in FIGS. 2A-4. In one example, memory arrays 102 include NAND storage.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art will recognize that memory device 100 may include other elements, several of which are not shown in FIG. 1, so as not to obscure the example embodiments described herein.

FIGS. 2A-2C show selected stages of manufacture of a semiconductor device 200. In one example, semiconductor device 200 includes a memory device, although the invention is not so limited. In one example, semiconductor device 200 includes transistors that are a part of circuitry on an edge of a memory array. In one example, semiconductor device 200 includes transistors that are a part of sense amplifier circuitry. In one example, semiconductor device 200 includes transistors that are a part of wordline driver circuitry. Although sense amplifiers and wordline drivers are used as examples, one of ordinary skill in the art, having the benefit of the present disclosure, will recognize that other semiconductor circuits also benefit from utilizing transistor arrangements as described.

In FIG. 2A, the semiconductor device 200 is shown, including a first device region 210 and a second device region 220. The semiconductor device 200 is formed on a semiconductor substrate 202, such as a silicon substrate. The first device region 210 includes a transistor gate 212, and source/drain regions 211 that are separated by the gate 212. In the example shown, dielectric spacers 214 are located on sides of the gate 212.

The second device region 220 includes a first transistor gate 222 and a second transistor gate 224. In the second device region 220, the first transistor gate 222 and the second transistor gate 224 are adjacent to outer source/drain regions 221 and a common source/drain region 223 located between the first transistor gate 222 and the second transistor gate 224. In the example of FIG. 2A, the first device region 210 is separated from the second device region 220 by an isolation structure 204 within the substrate 202.

A first dielectric layer 230 is shown over the first device region 210 and the second device region 220. The first dielectric layer 230 forms a direct interface with the transistor gates 212, 222, and 224 on a top surface of the transistor gates. The first dielectric layer 230 also forms a direct interface with the dielectric spacers 214. The first dielectric layer 230 also forms a direct interface with the isolation structure 204. In one example, the first dielectric layer 230 includes silicon and nitrogen. In one example, the first dielectric layer 230 includes stoichiometric silicon nitride (Si₃N₄). In one example, the first dielectric layer 230 includes silicon and oxygen and carbon. In one example, the first dielectric layer 230 includes silicon oxycarbide (SiOC). Any of a number of possible stoichiometric ratios of silicon, oxygen and carbon may be included in silicon oxycarbide.

FIG. 2B shows a subsequent stage of manufacture of the semiconductor device 200. In FIG. 2B, a second dielectric layer 240 is formed over the first dielectric layer 230 and the first device region 210 and the second device region 220. In the example of FIG. 2B, the second dielectric layer 240 forms a direct interface with the first dielectric layer 230. In one example, the semiconductor device 200 is planarized after deposition of the second dielectric layer 240 leaving portions of the second dielectric layer 240 that fill in topography of the semiconductor device 200 between the first device region 210 and the second device region 220.

The second dielectric layer 240 forms a second layer of two layers of different dielectric material. The layers 230 and 240 are both located over the isolation structure 204 in a region 205. In one example, the second dielectric layer 240 includes silicon and oxygen. In one example, the second dielectric layer 240 includes stoichiometric silicon dioxide (SiO₂).

A capping layer 206 is further shown in FIG. 2B. The capping layer 206 206 forms a direct interface with portions of the first dielectric layer 230, the second dielectric layer 240, and the transistor gates 212, 222, and 224. In one example, the capping layer 206 includes silicon and nitrogen. In one example, the capping layer 206 includes stoichiometric silicon nitride (Si₃N₄).

FIG. 2C shows another subsequent stage of manufacture of the semiconductor device 200. In FIG. 2C, a first contact 250 and a second contact 254 are shown. The first contact 250 connects to the outer source/drain regions 221, and the second contact 254 connects to the common source/drain region 223. As shown in FIG. 2C both the first contact 250 and the second contact 254 pass through the first dielectric layer 230. Also as shown in FIG. 2C, side surfaces 251 of both the first contact 250 and the second contact 254 are surrounded by the first dielectric 230. Conductor traces 252 and 256 are shown above the capping layer 206, and are used to connect the contacts 250, 254 to other circuitry.

A technical challenge with transistor configuration as dimensions and component pitch continue to shrink, is anisotropic etching of opening to form contacts such as the first contact 250 and the second contact 254. If the opening passes through different dielectric materials, one dielectric material may etch at a different rate that the other dielectric material. This can lead to contact openings with irregular cross section dimensions. When filled with conductor material, the resulting contact follows the irregular shape of the contact opening, and can form irregular shaped contacts.

Using configurations shown in the present disclosure, openings to form contacts pass through a single dielectric material and result in smaller, more predictable contacts. The use of a second dielectric material, such as the second dielectric layer 240, in addition to the first dielectric layer 230 provides other benefits, such as faster deposition and easier planarization before depositing the capping layer 206.

In one example, the first dielectric layer 230 is a conformal layer, that follows the shape of structures such as the gates 212, 222, 224, and the dielectric spacers 214. In the example of FIG. 2C, the first dielectric layer 230 forms arced portions 232 that conform to the dielectric spacers 214. In one example the first contact 250 passes through the arced portion 232 of the first dielectric layer 230. As shown, the first dielectric layer 230 and associated arced portion 232 are formed to a thickness sufficient for the first contact 250 to pass through where side surfaces 251 of the first contact 250 are surrounded by the arced portion 232 of the first dielectric layer 230.

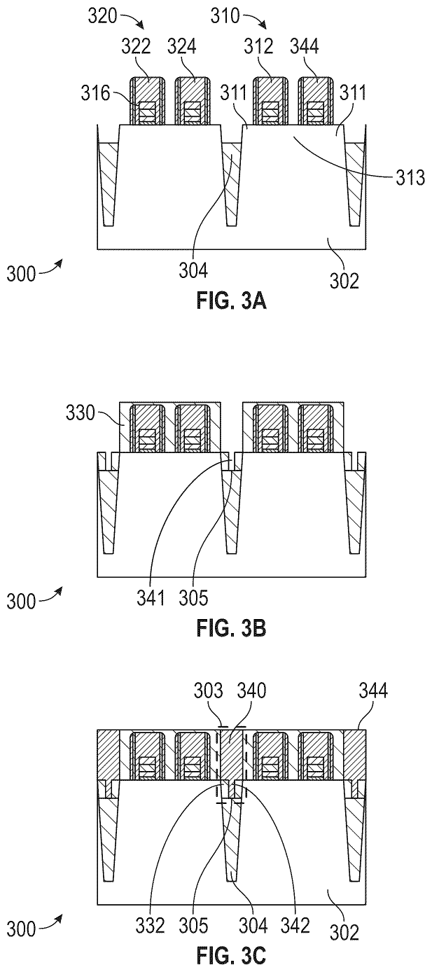

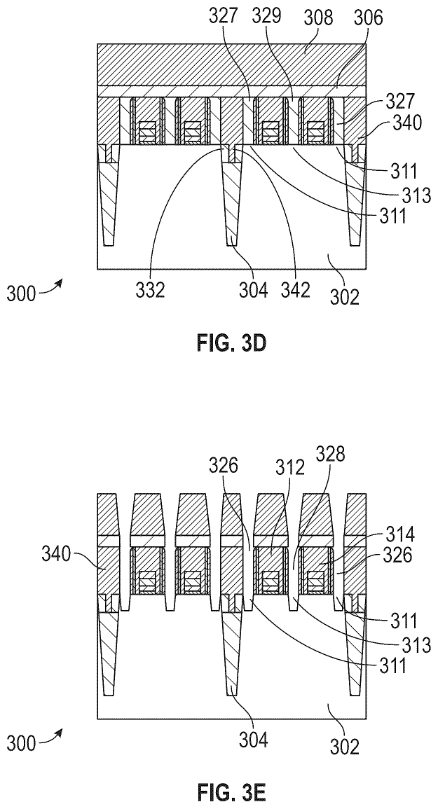

FIGS. 3A-3E show selected stages of manufacture of another example semiconductor device 300. In one example, semiconductor device 300 includes a memory device, although the invention is not so limited. Similar to semiconductor device 200, in one example, semiconductor device 300 includes transistors that are a part of circuitry on an edge of a memory array. In one example, semiconductor device 300 includes transistors that are a part of sense amplifier circuitry. In one example, semiconductor device 300 includes transistors that are a part of wordline driver circuitry. Although sense amplifiers and wordline drivers are used as examples, one of ordinary skill in the art, having the benefit of the present disclosure, will recognize that other semiconductor circuits also benefit from utilizing transistor arrangements as described.

In FIG. 3A, the semiconductor device 300 is shown, including a first device region 310 and a second device region 320. The semiconductor device 300 is formed on a semiconductor substrate 302, such as a silicon substrate. The first device region 310 includes a first gate stack 312 and a second gate stack 314. The second device region 320 includes a third gate stack 322 and a fourth gate stack 324. The first device region 310 further shows outer source/drain regions 311 and a common source/drain region 313 located between the first gate stack 312 and the second gate stack 314. In the example shown, dielectric spacers 316 are located on sides of the gate stacks. In the example of FIG. 3A, the first device region 310 is separated from the second device region 320 by an isolation structure 304 within the substrate 302.

FIG. 3B shows a first dielectric layer 330 over the first device region 310 and the second device region 320. The first dielectric layer 330 forms a direct interface with the gate stacks 312, 314, 322, and 324 on a top surface. The first dielectric layer 330 also forms a direct interface with the dielectric spacers 316. The first dielectric layer 330 also forms a direct interface with the isolation structure 304. In one example, the first dielectric layer 330 includes silicon and oxygen. In one example, the first dielectric layer 330 includes stoichiometric silicon dioxide (SiO₂). In FIG. 3B, the first dielectric layer 330 is shown after deposition, then etching. In one example, the first dielectric layer 330 is formed by atomic layer deposition, then etching, although the invention is not so limited. After etching, a cavity 341 is formed in the first dielectric layer 330 adjacent to the isolation structure 304, with a surface 305 of the isolation structure 304 exposed.

In FIG. 3C, a second dielectric layer 340 is formed over the first dielectric layer 330. In the example shown, the second dielectric layer 340 forms a direct interface with the first dielectric layer 330. In one example, the semiconductor device 300 is planarized after deposition of the second dielectric layer 340 leaving planarized surface 344. The second dielectric layer 340 forms a second layer of two layers of different dielectric material. The layers 330 and 340 are both located over the isolation structure 304 in a region 303.

In one example, the second dielectric layer 340 includes silicon and nitrogen. In one example, the second dielectric layer 340 includes stoichiometric silicon nitride (Si₃N₄). In one example, the second dielectric layer 340 includes silicon and oxygen and carbon. In one example, the second dielectric layer 340 includes silicon oxycarbide (SiOC). Any of a number of possible stoichiometric ratios of silicon, oxygen and carbon may be included in silicon oxycarbide. A portion 342 of the second dielectric layer 340 is shown making a direct interface with the isolation structure 304 at the surface 305. A portion 332 of the first dielectric layer 330 is also shown making a direct interface with the isolation structure 304 within the region 303 over the isolation structure 304.

In FIG. 3D, a capping layer 306 and top layer 308 are formed over the planarized surface 344. In one example, one or both of the capping layer 306 and top layer 308 include silicon and nitrogen although the invention is not so limited. In one example, e or both of the capping layer 306 and top layer 308 include includes stoichiometric silicon nitride (Si₃N₄). First portions 327 and second portions 329 of the first dielectric layer 330 are shown in FIG. 3D that are etch selective with respect to the second dielectric layer 340, and aligned with the outer source/drain regions 311 and the common source/drain region 313.

In FIG. 3E, first contact openings 326 are formed to access the outer source/drain regions 311 and second contact openings 328 are formed to access the common source/drain region 313. The first contact openings 326 and second contact openings 328 are subsequently filled with a conductor to form electrical contacts with the outer source/drain regions 311 and the common source/drain regions 313.

In the example of FIG. 3E, the first portions 327 and second portions 329 of the first dielectric layer 330 are removed, and the subsequent contact structures formed within the first contact openings 326 and second contact openings 328 are surrounded by the second dielectric layer 340. As noted above, openings to form contacts that pass through a single dielectric material and result in smaller, more predictable contacts.

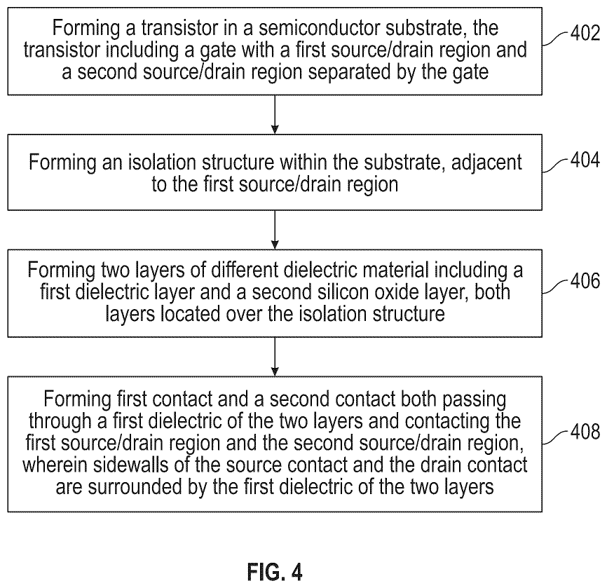

FIG. 4 shows a flow diagram of an example method of manufacture. In operation 402, a transistor is formed in a semiconductor substrate, the transistor including a gate with a first source/drain region and a second source/drain region separated by the gate. In operation 404, an isolation structure is formed within the substrate, adjacent to the first source/drain region. In operation 406, two layers of different dielectric material are formed, including a first dielectric layer and a second silicon oxide layer, both layers located over the isolation structure. In operation 408, a first contact and a second contact are formed with both the first contact and the second contact passing through a first dielectric of the two layers and contacting the first source/drain region and the second source/drain region, wherein side surfaces of the source contact and the drain contact are surrounded by the first dielectric of the two layers.

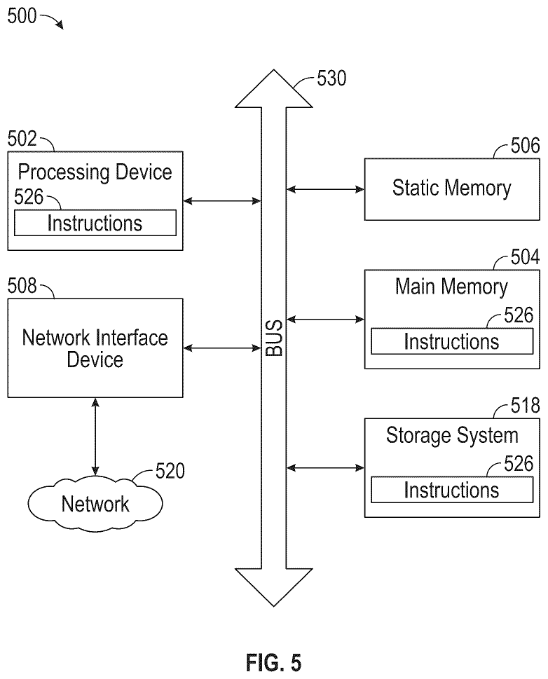

FIG. 5 illustrates a block diagram of an example machine (e.g., a host system) 500 which may include one or more transistors, isolation structures, semiconductor devices and/or memory systems as described above. As discussed above, machine 500 may benefit from enhanced memory performance from use of one or more of the described transistor structures and/or memory systems, facilitating improved performance of machine 500 (as for many such machines or systems, efficient reading and writing of memory can facilitate improved performance of a processor or other components that machine, as described further below.

In alternative embodiments, the machine 500 may operate as a standalone device or may be connected (e.g., networked) to other machines. In a networked deployment, the machine 500 may operate in the capacity of a server machine, a client machine, or both in server-client network environments. In an example, the machine 500 may act as a peer machine in peer-to-peer (P2P) (or other distributed) network environment. The machine 500 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 500 may include a processing device 502 (e.g., a hardware processor, a central processing unit (CPU), a graphics processing unit (GPU), a hardware processor core, or any combination thereof, etc.), a main memory 504 (e.g., read-only memory (ROM), dynamic random-access memory (DRAM) such as synchronous DRAM (SDRAM) or Rambus DRAM (RDRAM), etc.), a static memory 506 (e.g., static random-access memory (SRAM), etc.), and a storage system 518, some or all of which may communicate with each other via a communication interface (e.g., a bus) 530. In one example, the main memory 504 includes one or more memory devices as described in examples above.

The processing device 502 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 502 can also be one or more special-purpose processing devices such as an application specific integrated circuit (ASIC), a field programmable gate array (FPGA), a digital signal processor (DSP), network processor, or the like. The processing device 502 can be configured to execute instructions 526 for performing the operations and steps discussed herein. The computer system 500 can further include a network interface device 508 to communicate over a network 520.

The storage system 518 can include a machine-readable storage medium (also known as a computer-readable medium) on which is stored one or more sets of instructions 526 or software embodying any one or more of the methodologies or functions described herein. The instructions 526 can also reside, completely or at least partially, within the main memory 504 or within the processing device 502 during execution thereof by the computer system 500, the main memory 504 and the processing device 502 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 500 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 500 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 526 (e.g., software, programs, an operating system (OS), etc.) or other data are stored on the storage system 518 can be accessed by the main memory 504 for use by the processing device 502. The main memory 504 (e.g., DRAM) is typically fast, but volatile, and thus a different type of storage than the storage system 518 (e.g., an SSD), which is suitable for long-term storage, including while in an “off” condition. The instructions 526 or data in use by a user or the machine 500 are typically loaded in the main memory 504 for use by the processing device 502. When the main memory 504 is full, virtual space from the storage system 518 can be allocated to supplement the main memory 504; however, because the storage system 518 device is typically slower than the main memory 504, and write speeds are typically at least twice as slow as read speeds, use of virtual memory can greatly reduce user experience due to storage system latency (in contrast to the main memory 504, e.g., DRAM). Further, use of the storage system 518 for virtual memory can greatly reduce the usable lifespan of the storage system 518.

The instructions 526 may further be transmitted or received over a network 520 using a transmission medium via the network interface device 508 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 508 may include one or more physical jacks (e.g., Ethernet, coaxial, or phone jacks) or one or more antennas to connect to the network 520. In an example, the network interface device 508 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 500, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:

Example 1. A semiconductor device, comprising; a transistor formed in a substrate, the transistor including a gate with a first source/drain region and a second source/drain region separated by the gate; an isolation structure within the substrate, adjacent to the first source/drain region; two layers of different dielectric material including a first dielectric layer and a second silicon oxide layer, both layers located over the isolation structure; and a first contact and a second contact both passing through a first dielectric of the two layers and contacting the first source/drain region and the second source/drain region, wherein side surfaces of the first contact and the second contact are surrounded by the first dielectric of the two layers.

Example 2. The semiconductor device of example 1, wherein the first dielectric includes silicon nitride.

Example 3. The semiconductor device of example 1, wherein the first dielectric includes silicon oxycarbide.

Example 4. The semiconductor device of example 1, wherein the two layers of different dielectric material both form a direct interface with the isolation structure.

Example 5. The semiconductor device of example 1, wherein the first dielectric of the two layers forms a direct interface with the isolation structure and wherein the first dielectric is between the isolation structure and the silicon oxide layer.

Example 6. The semiconductor device of example 1, further including gate spacers on either side of the gate, and wherein the first dielectric of the two layers conforms over the gate and the gate spacers to form a conforming first layer.

Example 7. The semiconductor device of example 6, wherein one of the first contact or second contact passes through an arced portion of the conforming first layer.

Example 8. A semiconductor device, comprising; a pair of transistors formed in a substrate, the pair of transistors each including a gate, with a common first source/drain region located between the pair of transistors, and with outer second source/drain regions on outer sides of the pair of transistors; a pair of isolation structures within the substrate, each of the pair of isolation structures located adjacent to the outer source/drain regions; two layers of different dielectric material, both layers located over the isolation structures; and a number of contacts passing through a first dielectric of the two layers and contacting the common first source/drain region and the second outer source/drain regions, wherein side surfaces of the number of contacts are surrounded by the first dielectric of the two layers.

Example 9. The semiconductor device of example 8, wherein the first dielectric includes silicon nitride.

Example 10. The semiconductor device of example 8, wherein the first dielectric includes silicon oxycarbide.

Example 11. The semiconductor device of example 8, wherein a second dielectric of the two layers of different dielectric material includes silicon oxide.

Example 12. The semiconductor device of example 8, wherein the two layers of different dielectric material both form a direct interface with the isolation structure.

Example 13. The semiconductor device of example 8, wherein the first dielectric of the two layers forms a direct interface with the isolation structure and wherein the first dielectric is between the isolation structure and a second dielectric of the two layers.

Example 14. A semiconductor memory device, comprising; an array of memory cells; peripheral circuitry on one or more edges of the array of memory cells, wherein the peripheral circuitry includes one or more transistors formed in a substrate, the one or more transistors including; a gate with a first source/drain region and a second source/drain region separated by the gate; an isolation structure within the substrate, adjacent to the first source/drain region; two layers of different dielectric material, both layers located over the isolation structure; and a first contact and a second contact both passing through a first dielectric of the two layers and contacting the first source/drain region and the second source/drain region, wherein side surfaces of the first contact and the second contact are surrounded by the first dielectric of the two layers.

Example 15. The semiconductor device of example 14, wherein the first dielectric includes silicon nitride.

Example 16. The semiconductor device of example 14, wherein the first dielectric includes silicon oxycarbide.

Example 17. The semiconductor device of example 14, wherein a second dielectric of the two layers of different dielectric material includes silicon oxide.

Example 18. The semiconductor device of example 14, wherein the peripheral circuitry includes sense amplifier circuitry.

Example 19. The semiconductor device of example 14, wherein the peripheral circuitry includes wordline driver circuitry.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A semiconductor device, comprising;
a transistor formed in a substrate, the transistor including a gate with a first source/drain region and a second source/drain region separated by the gate;
an isolation structure within the substrate, adjacent to the first source/drain region;
two layers of different dielectric material including a first dielectric layer and a second silicon oxide layer, both layers located over the isolation structure; and
a first contact and a second contact both passing through a first dielectric of the two layers and contacting the first source/drain region and the second source/drain region, wherein side surfaces of the first contact and the second contact are surrounded by the first dielectric of the two layers.

2. The semiconductor device of claim 1, wherein the first dielectric includes silicon nitride.

3. The semiconductor device of claim 1, wherein the first dielectric includes silicon oxycarbide.

4. The semiconductor device of claim 1, wherein the two layers of different dielectric material both form a direct interface with the isolation structure.

5. The semiconductor device of claim 1, wherein the first dielectric of the two layers forms a direct interface with the isolation structure and wherein the first dielectric is between the isolation structure and the silicon oxide layer.

6. The semiconductor device of claim 1, further including gate spacers on either side of the gate, and wherein the first dielectric of the two layers conforms over the gate and the gate spacers to form a conforming first layer.

7. The semiconductor device of claim 6, wherein one of the first contact or second contact passes through an arced portion of the conforming first layer.

8. A semiconductor device, comprising;
a pair of transistors formed in a substrate, the pair of transistors each including a gate, with a common first source/drain region located between the pair of transistors, and with outer second source/drain regions on outer sides of the pair of transistors;
a pair of isolation structures within the substrate, each of the pair of isolation structures located adjacent to the outer source/drain regions;
two layers of different dielectric material, both layers located over the isolation structures; and
a number of contacts passing through a first dielectric of the two layers and contacting the common first source/drain region and the second outer source/drain regions, wherein side surfaces of the number of contacts are surrounded by the first dielectric of the two layers.

9. The semiconductor device of claim 8, wherein the first dielectric includes silicon nitride.

10. The semiconductor device of claim 8, wherein the first dielectric includes silicon oxycarbide.

11. The semiconductor device of claim 8, wherein a second dielectric of the two layers of different dielectric material includes silicon oxide.

12. The semiconductor device of claim 8, wherein the two layers of different dielectric material both form a direct interface with the isolation structure.

13. The semiconductor device of claim 8, wherein the first dielectric of the two layers forms a direct interface with the isolation structure and wherein the first dielectric is between the isolation structure and a second dielectric of the two layers.

14. A semiconductor memory device, comprising;
an array of memory cells;
peripheral circuitry on one or more edges of the array of memory cells, wherein the peripheral circuitry includes one or more transistors formed in a substrate, the one or more transistors including;
a gate with a first source/drain region and a second source/drain region separated by the gate;
an isolation structure within the substrate, adjacent to the first source/drain region;
two layers of different dielectric material, both layers located over the isolation structure; and
a first contact and a second contact both passing through a first dielectric of the two layers and contacting the first source/drain region and the second source/drain region, wherein side surfaces of the first contact and the second contact are surrounded by the first dielectric of the two layers.

15. The semiconductor device of claim 14, wherein the first dielectric includes silicon nitride.

16. The semiconductor device of claim 14, wherein the first dielectric includes silicon oxycarbide.

17. The semiconductor device of claim 14, wherein a second dielectric of the two layers of different dielectric material includes silicon oxide.

18. The semiconductor device of claim 14, wherein the peripheral circuitry includes sense amplifier circuitry.

19. The semiconductor device of claim 14, wherein the peripheral circuitry includes wordline driver circuitry.
